(19) United States
(12) Patent Application Publication
(10) Pub. No.: US 2022/0214109 A1
(43) Pub. Date: Jul. 7, 2022

(54) LIGHT IRRADIATION TYPE HEAT TREATMENT APPARATUS AND HEAT TREATMENT METHOD

(71) Applicant: SCREEN Holdings Co., Ltd., Kyoto (JP)

(72) Inventors: Takahiro YAMADA, Kyoto-shi (JP); Masashi FURUKAWA, Kyoto-shi (JP)

(21) Appl. No.: 17/531,850

(22) Filed: Nov. 22, 2021

(30) Foreign Application Priority Data
Jan. 7, 2021 (JP) 2021-001651

(51) Int. Cl. F27B 17/00; H05B 3/00; F27D 5/00; F27D 11/00

(52) U.S. Cl. CPC F27B 17/0025; H05B 3/0047; F27D 7/02; F27D 11/00; F27D 5/0037

(57) ABSTRACT

A plurality of flash lamps are disposed on an upper side of a chamber housing a semiconductor wafer and a plurality of LED lamps are disposed on a lower side thereof. A surface of a semiconductor wafer preheated by light irradiation from a plurality of LED lamps is irradiated with a flash of light from a flash lamp. The LED lamps emit light having a wavelength of 900 nm or less. The light radiated from the LED lamps passes through a quartz lower chamber window, and then emitted to the semiconductor wafer. The light with the wavelength of 900 nm or less radiated from the LED lamps is also favorably absorbed by the semiconductor wafer in a low temperature range of 500° C. or less, and is hardly absorbed by the quartz lower chamber window. Thus, the semiconductor wafer can be efficiently heated by the LED lamps.

### BACKGROUND OF THE INVENTION

### Field of the Invention

The present invention relates to a heat treatment apparatus that irradiates a thin plate-like precision electronic substrate (hereinafter referred to simply as a “substrate”) such as a semiconductor wafer with light to heat the substrate and a heat treatment method.

### Description of the Background Art

A flash lamp anneal (FLA) which heats a semiconductor wafer for an extremely short time in a process of manufacturing a semiconductor device attracts attention. The flash lamp anneal is a heat treatment technique of irradiating a surface of a semiconductor wafer with a flash of light using a xenon flash lamp (a simple term of “a flash lamp” means a xenon flash lamp hereinafter), thereby increasing a temperature of only the surface of the semiconductor wafer in an extremely short time (several milliseconds or less).

A radiation spectral distribution of the xenon flash lamp ranges from an ultraviolet region to a near-infrared region, thus a wavelength of the xenon flash lamp is shorter than that of a conventional halogen lamp, and almost coincides with a basic absorption band of a silicon semiconductor wafer. Thus, when the semiconductor wafer is irradiated with a flash of light emitted from the xenon flash lamp, the temperature of the semiconductor wafer can be rapidly increased with less transmitted light. It is also known that a flash light emission for the extremely short time of several milliseconds or less can selectively increase a temperature of only a region near the surface of the semiconductor wafer.

Such a flash lamp anneal is used for processing requiring a heating for an extremely short time, for example, typically an activation of impurity implanted into the semiconductor wafer. When the surface of the semiconductor wafer into which the impurity is implanted by an ion implantation method is irradiated with a flash of light from the flash lamp, the surface of the semiconductor wafer can be increased to an activation temperature only for the extremely short time, thus only an impurity activation can be executed without deeply diffusing the impurity.

Used typically as an apparatus for executing such a flash lamp anneal is a heat treatment apparatus in which a flash lamp is provided on an upper side of a chamber housing a semiconductor wafer and a halogen lamp is provided on a lower side thereof (for example, US 2011/0262115). In the apparatus disclosed in US 2011/0262115, the semiconductor wafer is preheated by light irradiation from the halogen lamp, and subsequently, the surface of the semiconductor wafer is irradiated with a flash of light from the flash lamp. The preheating is performed by the halogen lamp because the surface of the semiconductor wafer hardly reaches to a target temperature only by the flash light irradiation.

However, when the preheating is performed by the halogen lamp, it takes a certain period of time before the halogen lamp reaches a target output after it is turned on, and a heat irradiation tentatively continues after the halogen lamp is turned off, thus there is a problem that a diffusion length of impurity implanted into the semiconductor wafer is relatively increased.

The halogen lamp mainly emits infrared light having a relatively long wavelength. With regard to a spectral absorption index of a silicon semiconductor wafer, an absorption index of infrared light having a long wavelength of 1 μm or more is low in a low temperature range of 500° C. or less. That is to say, the semiconductor wafer having a temperature of 500° C. or less does not absorb infrared light emitted from the halogen lamp so much, thus an inefficient heating is performed in an initial stage of preheating.

The light emitted from the halogen lamp passes through a quartz window provided in a chamber and then irradiates the semiconductor wafer. With regard to a spectral transmission rate of quartz, a transmission rate of light in relatively a long wavelength range is low. That is to say, part of light emitted from the halogen lamp is absorbed by the quartz window, thus efficiency of preheating by the halogen lamp is further reduced.

Furthermore, the halogen lamp has a rod-like shape longer than a diameter of the semiconductor wafer, thus there is also a problem that the halogen lamp has a low degree of freedom in adjusting an in-plane temperature distribution of the semiconductor wafer.

### SUMMARY OF THE INVENTION

The present invention is directed to a heat treatment apparatus heating a substrate by irradiating the substrate with light.

According to one aspect of the present invention, a heat treatment apparatus includes: a chamber housing a substrate; a holder the substrate in the chamber; a plurality of LED lamps provided on one side of the chamber to irradiate the substrate held by the holder with light having a wavelength of 900 nm or less; a flash lamp provided on another side of the chamber to irradiate the substrate held by the holder with a flash of light; and a quartz window provided in the chamber and disposed between the holder and the plurality of LED lamps.

The heat treatment apparatus includes the plurality of LED lamps irradiating the substrate with the light having the wavelength of 900 nm or less, thus the light is also favorably absorbed by the substrate in the low temperature range, and the substrate can be efficiently heated.

It is preferable that the plurality of LED lamps are concentrically disposed so that a central axis thereof coincides with a central axis of the substrate held by the holder.

Uniformity of the in-plane temperature distribution of the substrate can be improved.

The plurality of LED lamps are preferably disposed so that an outer periphery of a concentric circle is closer to the substrate.

The plurality of LED lamps are preferably disposed to be inclined with respect to a horizontal plane so that the center of a concentric circle is directed to a peripheral edge part of the substrate.

The plurality of LED lamps preferably have higher emission intensity at an outer periphery of a concentric circle.

Illuminance of the peripheral edge part of the substrate where decrease in a temperature easily occurs is relatively high, and uniformity of the in-plane temperature distribution of the substrate can be improved.

The plurality of LED lamps preferably have a longer irradiation time at an outer periphery of a concentric circle.

The irradiation time of irradiating the peripheral edge part of the substrate where decrease in a temperature easily occurs is relatively long, and uniformity of the in-plane temperature distribution of the substrate can be improved.

The present invention is also directed to a heat treatment method of heating a substrate by irradiating the substrate with light.

According to one aspect of the present invention, a heat treatment method includes: (a) irradiating a substrate held by a holder in a chamber with light having a wavelength of 900 nm or less from a plurality of LED lamps provided on one side of the chamber to heat the substrate; and (b) irradiating the substrate held by the holder with a flash of light from a flash lamp provided on another side of the chamber to heat the substrate.

The substrate is irradiated with the light having the wavelength of 900 nm or less from the plurality of LED lamps to be heated, thus the light is also favorably absorbed by the substrate in the low temperature range, and the substrate can be efficiently heated.

It is preferable that the plurality of LED lamps are concentrically disposed so that a central axis thereof coincides with a central axis of the substrate held by the holder.

Uniformity of the in-plane temperature distribution of the substrate can be improved.

A height position of the plurality of LED lamps are preferably adjusted so that an outer periphery of a concentric circle is closer to the substrate.

The plurality of LED lamps are preferably inclined with respect to a horizontal plane so that a center of a concentric circle is directed more to a peripheral edge part of the substrate.

Emission intensity of the plurality of LED lamps are preferably adjusted so that emission intensity is higher at an outer periphery of a concentric circle.

Illuminance of the peripheral edge part of the substrate where decrease in a temperature easily occurs is relatively high, and uniformity of the in-plane temperature distribution of the substrate can be improved.

An irradiation time of the plurality of LED lamps is preferably adjusted so that an irradiation time is longer at an outer periphery of a concentric circle.

The irradiation time of irradiating the peripheral edge part of the substrate where decrease in a temperature easily occurs is relatively long, and uniformity of the in-plane temperature distribution of the substrate can be improved.

Accordingly, an object of the present invention is to efficiently heat a substrate.

These and other objects, features, aspects and advantages of the present invention will become more apparent from the following detailed description of the present invention when taken in conjunction with the accompanying drawings.

### BRIEF DESCRIPTION OF THE DRAWING

FIG. 1 is a longitudinal sectional view illustrating a configuration of a heat treatment apparatus according to the present invention.

FIG. 2 is a perspective view illustrating an entire external appearance of a holder.

FIG. 3 is a plan view of a susceptor.

FIG. 4 is a sectional view of the susceptor.

FIG. 5 is a plan view of a transfer mechanism.

FIG. 6 is a side view of the transfer mechanism.

FIG. 7 is a plan view illustrating an arrangement of a plurality of LED lamps.

FIG. 8 is a drawing schematically illustrating an arrangement configuration of a plurality of LED lamps according to a second embodiment.

FIG. 9 is a drawing schematically illustrating an arrangement configuration of a plurality of LED lamps according to a third embodiment.

### DESCRIPTION OF THE PREFERRED EMBODIMENTS

Embodiments according to the present invention will now be described in detail with reference to the drawings.

### First Embodiment

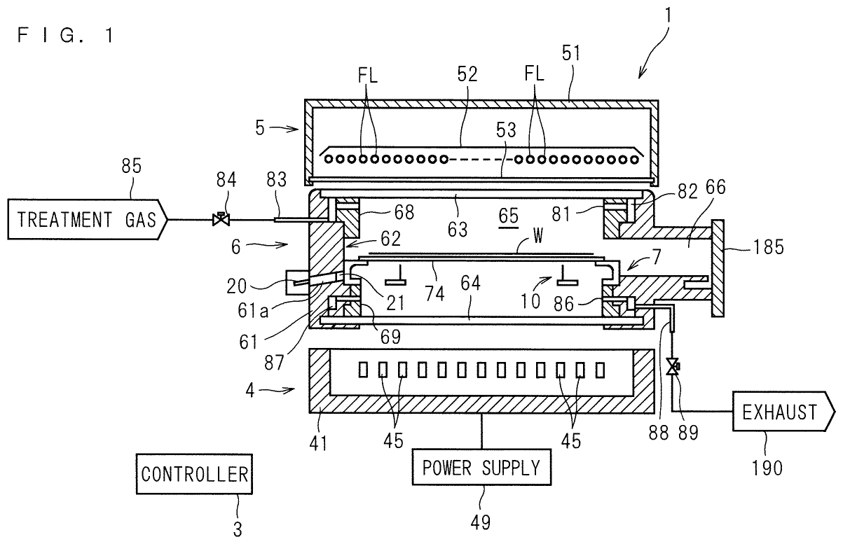

FIG. 1 is a longitudinal sectional view illustrating a configuration of a heat treatment apparatus 1 according to the present invention. The heat treatment apparatus 1 in FIG. 1 is a flash lamp annealer for heating a disk-shaped semiconductor wafer W serving as a substrate by irradiating the semiconductor wafer W with a flash of light. A size of the semiconductor wafer W to be treated is not particularly limited. For example, the semiconductor wafer W to be treated has a diameter of 300 mm or 450 mm. It should be noted that dimensions of components and the number of components are illustrated in exaggeration or in simplified form, as appropriate, in FIG. 1 and the subsequent drawings for the sake of easier understanding.

The heat treatment apparatus 1 includes a chamber 6 for housing the semiconductor wafer W, a flash heating part 5 including a plurality of built-in flash lamps FL, and an LED heating part 4 including a plurality of built-in light emitting diode (LED) lamps 45. The flash heating part 5 is provided over the chamber 6, and the LED heating part 4 is provided under the chamber 6. The heat treatment apparatus 1 further includes a holder 7 provided inside the chamber 6 and for holding the semiconductor wafer W in a horizontal attitude, and a transfer mechanism 10 provided inside the chamber 6 and for transferring the semiconductor wafer W between the holder 7 and the outside of the heat treatment apparatus 1. The heat treatment apparatus 1 further includes a controller 3 for controlling each operating mechanism provided in the LED heating part 4, the flash heating part 5, and the chamber 6 to cause each operating mechanism to execute a heat treatment on the semiconductor wafer W.

The chamber 6 is configured such that upper and lower chamber windows made of quartz are mounted to the top and bottom, respectively, of a tubular chamber side portion 61. The chamber side portion 61 has a generally tubular shape having an open top and an open bottom. An upper chamber window 63 is mounted to block the top opening of the chamber side portion 61, and a lower chamber window 64 is mounted to block the bottom opening thereof. The upper chamber window 63 forming a ceiling of the chamber 6 is a disk-shaped member made of quartz, and serves as a quartz window that transmits a flash of light emitted from the flash heating part 5 therethrough into the chamber 6. The lower chamber window 64 forming a floor of the chamber 6 is also a disk-shaped member made of quartz, and serves as a quartz window that transmits light emitted from the LED heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds the semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of the semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, the semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared radiation emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. Thus, the radiation thermometer 20 is provided obliquely lower side of the susceptor 74. A transparent window 21 made of barium fluoride material transparent to infrared radiation in a wavelength range measurable with the radiation thermometer 20 is mounted to an end portion of the through hole 61a which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is inserted at some midpoint in the gas supply pipe 83. When the valve 84 is opened, the treatment gas is supplied from the treatment gas supply source 85 to the buffer space 82. The treatment gas which has flowed into the buffer space 82 flows in a spreading manner within the buffer space 82 which is lower in fluid resistance than the gas supply opening 81, and is supplied through the gas supply opening 81 into the heat treatment space 65. An inert gas such as nitrogen (N₂), a reactive gas such as hydrogen (H₂) and ammonia (NH₃), or a gas mixture thereof, for example, can be used as the treatment gas (nitrogen gas in the present embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is inserted at some midpoint in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be a utility in a factory in which the heat treatment apparatus 1 is installed.

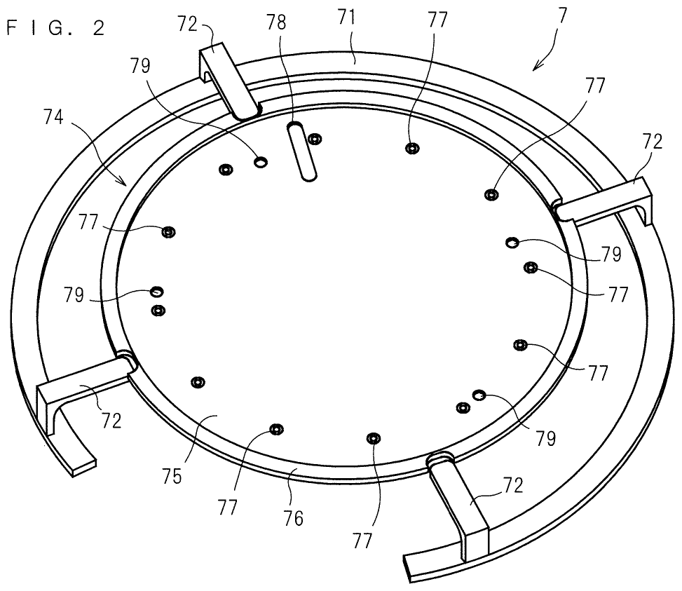

FIG. 2 is a perspective view illustrating an entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by a wall surface of the chamber 6 by being placed on the bottom surface of the recessed portion 62 (with reference to FIG. 1). The multiple coupling portions 72 (in the present embodiment, four coupling portions 72) are mounted upright on the upper surface of the base ring 71 and arranged in a circumferential direction of the annular shape thereof. The coupling portions 72 are also quartz members, and are rigidly secured to the base ring 71 by welding.

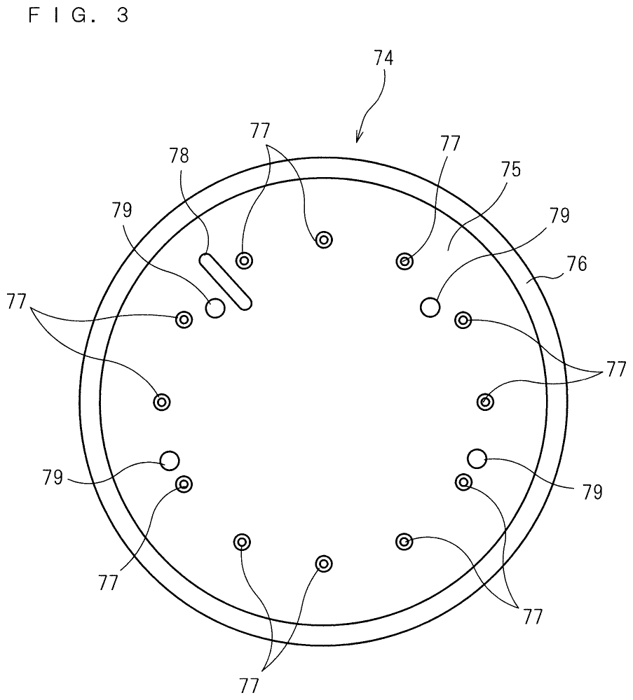

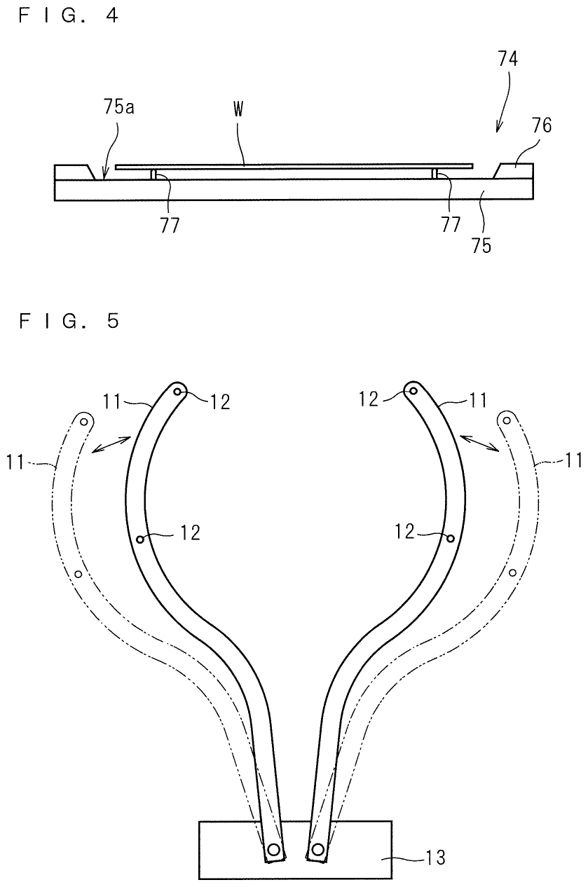

The susceptor 74 is supported by the four coupling portions 72 provided on the base ring 71. FIG. 3 is a plan view of the susceptor 74. FIG. 4 is a cross-sectional view of the susceptor 74. The susceptor 74 includes a holding plate 75, a guide ring 76, and a plurality of substrate support pins 77. The holding plate 75 is a generally circular planar member made of quartz. A diameter of the holding plate 75 is greater than that of the semiconductor wafer W. In other words, the holding plate 75 has a size, as seen in plan view, greater than that of the semiconductor wafer W.

The guide ring 76 is provided on a peripheral part of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present embodiment, a total of 12 substrate support pins 77 provided upright are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral part of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

The semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W can be supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. A thickness of the guide ring 76 is greater than the height of the substrate support pins 77. Thus, the guide ring 76 prevents the horizontal misregistration of the semiconductor wafer W supported by the substrate support pins 77.

As illustrated in FIGS. 2 and 3, an opening 78 is formed in the holding plate 75 of the susceptor 74 so as to extend vertically through the holding plate 75 of the susceptor 74. The opening 78 is provided for the radiation thermometer 20 to receive radiation (infrared radiation) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. The holding plate 75 of the susceptor 74 further includes four through holes 79 bored therein and designed so that lift pins 12 of the transfer mechanism 10 to be described later pass through the through holes 79, respectively, to transfer the semiconductor wafer W.

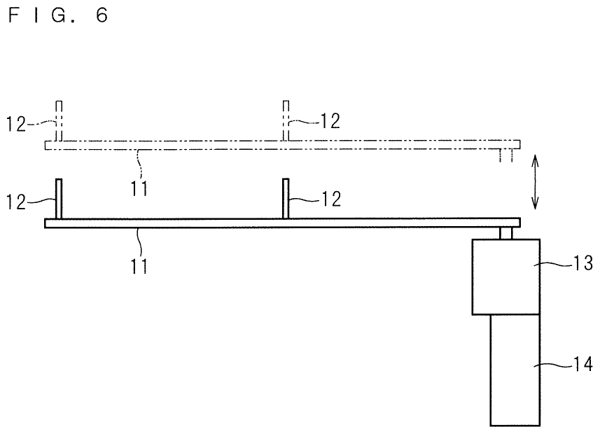

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which the semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in a plan view. The horizontal movement mechanism 13 may be of the type which causes individual motors to pivot the transfer arms 11 respectively or of the type which uses the linkage mechanism to cause a single motor to pivot the pair of transfer arms 11 in cooperative relation.

The pair of transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct a flash of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of the semiconductor wafer W held by the holder 7 (that is, in the horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if high voltage is applied to the trigger electrode to produce an electrical breakdown, electricity stored in the capacitor flows momentarily in the glass tube, and xenon atoms or molecules are excited at this time to cause light emission. This xenon flash lamp FL has the property of being capable of emitting extremely intense light as compared with a light source that stays lit continuously such as a halogen lamp because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect the flash of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The LED heating part 4 provided under the chamber 6 includes an enclosure 41 incorporating the multiple LED lamps 45. The LED heating part 4 directs light from under the chamber 6 through the lower chamber window 64 toward the heat treatment space 65 to heat the semiconductor wafer W by means of the plurality of LED lamps 45.

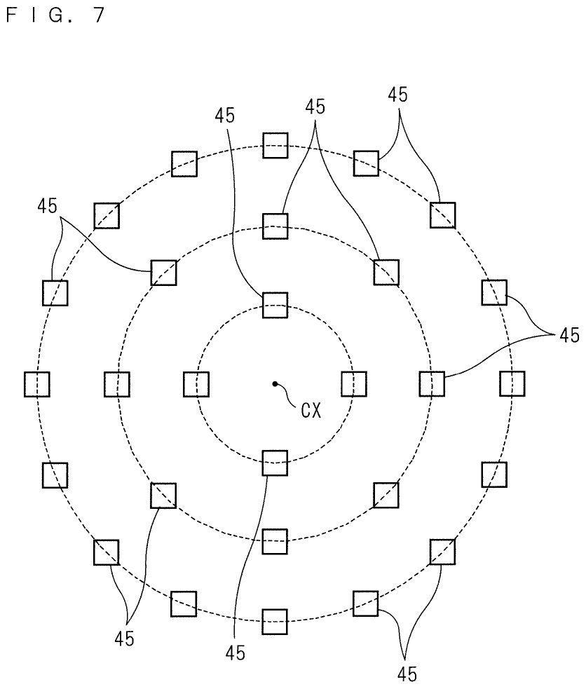

FIG. 7 is a plan view illustrating an arrangement of the plurality of LED lamps 45. The several thousands of LED lamps 45 are disposed in the LED heating part 4, however, in FIG. 7, the number thereof is illustrated in a simplified manner for convenience of illustration. Each LED lamp 45 is a point light source lamp having a quadrangular prism shape while a conventional halogen lamp is a rod-like lamp. In the first embodiment, the plurality of LED lamps 45 are arranged along the main surface of the semiconductor wafer W held by the holder 7 (that is to say, along a horizontal direction). Thus, a plane defined by the arrangement of the plurality of LED lamps 45 is a horizontal plane.

As illustrated in FIG. 7, the plurality of LED lamps 45 are concentrically disposed. More specifically, the plurality of LED lamps 45 are concentrically disposed so that the central axis thereof coincides with a central axis CX of the semiconductor wafer W held by the holder 7. The plurality of LED lamps 45 are disposed at regular intervals in each concentric circle. For example, in the example illustrated in FIG. 7, the eight LED lamps 45 are evenly disposed at a 45-degrees interval in a second innermost concentric circle.

The LED lamp 45 includes a light emitting diode. The light emitting diode is a type of a diode, and emits light by electroluminescence effect when voltage is applied in a forward direction. The LED lamp 45 according to the present embodiment emits light having a wavelength of 900 nm or less. The LED lamp 45 is a continuous lighting lamp that emits light continuously for at least not less than one second.

Voltage is applied to each of the plurality of LED lamps 45 from a power supply part 49 (FIG. 1), thus the LED lamps 45 emit light. The power supply part 49 individually adjusts power supplied to each of the plurality of LED lamps 45 under control of the controller 3. That is to say, the power supply part 49 can individually adjust emission intensity and a light emission time of each of the plurality of LED lamps 45 disposed in the LED heating part 4.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like therein. The CPU in the controller 3 executes a predetermined treatment program, whereby the processes in the heat treatment apparatus 1 proceed.

The heat treatment apparatus 1 further includes, in addition to the aforementioned configuration, various cooling structures to prevent an excessive temperature rise in the LED heating part 4, the flash heating part 5, and the chamber 6 because of the heat energy generated from the LED lamps 45 and the flash lamps FL during the heat treatment of the semiconductor wafer W. As an example, a water cooling tube (not shown) is provided in the walls of the chamber 6. Also, the LED heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

A treatment operation in the heat treatment apparatus 1 is described next. A typical heat treatment operation performed on a normal semiconductor wafer (product wafer) W which becomes a product is described herein. The semiconductor wafer W to be treated is a silicon (Si) semiconductor substrate into which impurity is implanted by ion implantation as a preceding process. The impurity is activated by an anneal processing performed by the heat treatment apparatus 1. The process procedure in the semiconductor wafer W described hereinafter proceeds when the controller 3 controls each operation mechanism of the heat treatment apparatus 1.

Firstly, the valve 84 for gas supply is opened and the valve 89 for gas exhaust is opened to start gas supply and exhaust within the chamber 6 prior to the treatment of the semiconductor wafer W. When the valve 84 is opened, nitrogen gas is supplied from the gas supply opening 81 into the heat treatment space 65. Also, when the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports the semiconductor wafer W to be processed through the transport opening 66 into the heat treatment space 65 in the chamber 6. At this time, there is a possibility that the atmosphere outside the apparatus is carried into the heat treatment space 65 as the semiconductor wafer W is transported into the heat treatment space 65, however, the nitrogen gas is continuously supplied into chamber 6, thus the nitrogen gas flows through the transport opening 66 and it is possible to minimize an outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof where a pattern is formed and the impurity is implanted is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held in the horizontal attitude from below by the susceptor 74 of the holder 7 formed of quartz, the plurality of LED lamps 45 in the LED heating part 4 are turned on and preheating (or assist-heating) is started. Light emitted from the plurality of LED lamps 45 is transmitted through the lower chamber window 64 and the susceptor 74 both made of quartz, and impinges on the lower surface of the semiconductor wafer W. By receiving light irradiation from the LED lamps 45, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the LED lamps 45.

The temperature of the semiconductor wafer W which is on the increase by the irradiation with light from the LED lamps 45 is measured with the radiation thermometer 20. The measured temperature of the semiconductor wafer W is transmitted to the controller 3. The controller 3 controls the power supply part 49 to adjust the output from the LED lamps 45 while monitoring whether or not the temperature of the semiconductor wafer W which is on the increase by the irradiation with light from the LED lamps 45 reaches a predetermined preheating temperature T1. In other words, the controller 3 effects feedback control of the output from the LED lamps 45 so that the temperature of the semiconductor wafer W is equal to the preheating temperature T1, based on a value measured with the radiation thermometer 20. The preheating temperature T1 is set to be approximately 200° C. to 800° C., and is preferably set to be approximately 350° C. to 600° C., so that there is no possibility of diffusion of the impurity added to the semiconductor wafer W caused by the heat (600° C. in the present embodiment).

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured with the radiation thermometer 20 reaches the preheating temperature T1, the controller 3 adjusts the output from the LED lamps 45 to maintain the temperature of the semiconductor wafer W at approximately the preheating temperature T1.

The flash lamps FL in the flash heating part 5 irradiate the front surface of the semiconductor wafer W held by the susceptor 74 with a flash of light at a time when a predetermined time period has elapsed since the temperature of the semiconductor wafer W reaches the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such a flash of light achieves the flash heating of the semiconductor wafer W.

The flash heating, which is achieved by the emission of a flash of light from the flash lamps FL, is capable of increasing the temperature of the front surface of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The temperature of the front surface of the semiconductor wafer W is increased instantaneously to a treatment temperature T2 of 1000° C. or more by the flash light irradiation from the flash lamps FL, and after the impurity implanted into the semiconductor wafer W is activated, the temperature of the front surface decreases rapidly. In this manner, the heat treatment apparatus 1 can increase and decrease the temperature of the front surface of the semiconductor wafer W in the extremely short time, thus the diffusion of the impurity implanted into the semiconductor wafer W caused by the heat can be suppressed and the impurity can be activated. The time required for the activation of the impurity is extremely shorter than the time required for a heat diffusion, thus the activation is completed in a short time of approximately 0.1 milliseconds to 100 milliseconds in which the diffusion does not occur.

When the flash heating treatment is finished, the LED lamps 45 are turned off after an elapse of a predetermined time. Accordingly, the temperature of the semiconductor wafer W decreases rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement with the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

In the present embodiment, the semiconductor wafer W is preheated to the preheating temperature T1 by the irradiation with light from the LED lamps 45, and subsequently the temperature of the front surface of the semiconductor wafer W is increased to a treatment temperature T2 by irradiating the front surface thereof with a flash of light from the flash lamps FL. The LED lamp 45 has a high-speed rise and fall output compared with a conventional halogen lamp. That is to say, the LED lamps 45 are turned on and reach a target output almost at the same time, and perform no heat irradiation after the LED lamps 45 are turned off. According to such a feature of the LED lamp 45, an unintended unnecessary diffusion of the impurity implanted into the semiconductor wafer W can be suppressed.

The LED lamp 45 emits light having a wavelength of 900 nm or less. With regard to a spectral absorption index of the silicon semiconductor wafer W, an absorption index of infrared light having a wavelength of 1 μm or more is low in a low temperature range of 500° C. or less, however, an absorption index of light having a wavelength of 900 nm or less is relatively high. That is to say, the semiconductor wafer W preferably absorbs light emitted from the LED lamps 45 even in a low temperature range of 500° C. or less. Accordingly, even when the temperature of the semiconductor wafer W is 500° C. or less at an initial stage of preheating, the semiconductor wafer W can be efficiently heated by the LED lamps 45.

Light having a wavelength of 900 nm or less has almost no temperature dependency in an absorption index of absorbing silicon. That is to say, even when the temperature of the semiconductor wafer W is increased from a low temperature to a high temperature in a process of preheating, the absorption index of the semiconductor wafer W hardly fluctuates as for the light emitted from the LED lamps 45. Thus, the semiconductor wafer W can be stably heated by performing the preheating by the irradiation with light from the LED lamps 45. There is almost no fluctuation of emissivity, the temperature of the semiconductor wafer W can be stably measured with radiation thermometer 20.

The quartz lower chamber window 64 is located between the plurality of LED lamps 45 and the holder 7. Thus, the light radiated from the LED lamps 45 passes through the quartz lower chamber window 64, and then emitted to the semiconductor wafer W. With regard to a spectral transmission rate of quartz, a transmission rate of light in relatively a long wavelength range is low, however, a transmission rate of light having a wavelength of 900 nm or less is high. Accordingly, the light radiated from the LED lamps 45 is hardly absorbed by the lower chamber window 64. Thus, the semiconductor wafer W can be further efficiently heated by the LED lamps 45.

Furthermore, in the first embodiment, the plurality of LED lamps 45 are concentrically disposed so that the central axis thereof coincides with the central axis CX of the semiconductor wafer W held by the holder 7. Accordingly, in-plane uniformity of a temperature distribution of the semiconductor wafer W at the time of preheating can be improved.

### Second Embodiment

Next, a second embodiment according to the present invention will be described. A whole configuration of the heat treatment apparatus 1 in the second embodiment is substantially the same as that of the first embodiment. A procedure of processing the semiconductor wafer W in the heat treatment apparatus 1 according to the second embodiment is also similar to that in the first embodiment. The second embodiment is different from the first embodiment in an arrangement configuration of the plurality of LED lamps 45.

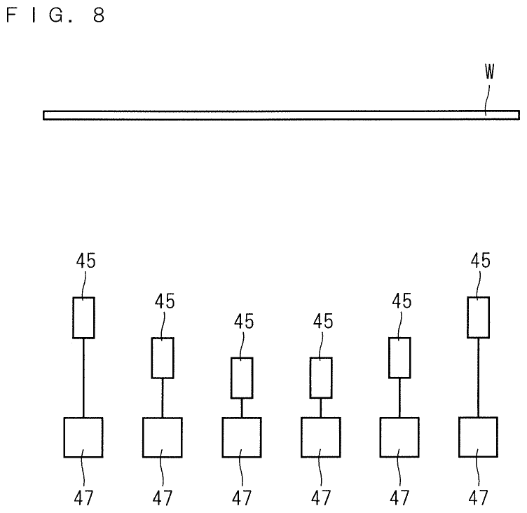

FIG. 8 is a drawing schematically illustrating an arrangement configuration of the plurality of LED lamps 45 according to the second embodiment. Also in the second embodiment, the plurality of LED lamps 45 are concentrically disposed so that the central axis thereof coincides with the central axis CX of the semiconductor wafer W held by the holder 7 when seen from an upper side.

In the second embodiment, a height position adjusting mechanism 47 is provided to each of the plurality of LED lamps 45. The height position adjusting mechanism 47 can move up and down the LED lamps 45 to adjust the height position thereof.

In the second embodiment, as illustrated in FIG. 8, the plurality of height position adjusting mechanisms 47 adjusts the height position of the plurality of LED lamps 45 so that an outer periphery of the concentric circle is closer to the semiconductor wafer W. That is to say, the height position of the LED lamp 45 in the outer periphery of the concentric circle is higher, and the height position of the LED lamp 45 closer to a center of the concentric circle is lower.

When the semiconductor wafer W is preheated by the plurality of LED lamps 45, the temperature of the peripheral edge part where a heat radiation is large compared with a center portion of the wafer tends to decrease easily. In the second embodiment, the height position of each of the plurality of LED lamps 45 is individually adjusted by the height position adjusting mechanism 47, and the plurality of LED lamps 45 are disposed so that the outer periphery of the concentric circle is closer to the semiconductor wafer W. Accordingly, when the semiconductor wafer W is irradiated with light from the plurality of LED lamps 45, illuminance of the peripheral edge part of the semiconductor wafer W is relatively high compared with the center portion thereof, and uniformity of the in-plane temperature distribution of the semiconductor wafer W can be improved.

### Third Embodiment

Next, a third embodiment according to the present invention will be described. A whole configuration of the heat treatment apparatus 1 in the third embodiment is substantially the same as that of the first embodiment. A procedure of processing the semiconductor wafer W in the heat treatment apparatus 1 according to the third embodiment is also similar to that in the first embodiment. The third embodiment is different from the first embodiment in an arrangement configuration of the plurality of LED lamps 45.

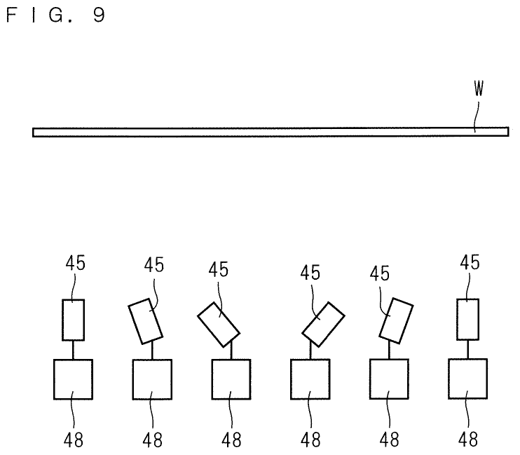

FIG. 9 is a drawing schematically illustrating an arrangement configuration of the plurality of LED lamps 45 according to the third embodiment. Also in the third embodiment, the plurality of LED lamps 45 are concentrically disposed so that the central axis thereof coincides with the central axis CX of the semiconductor wafer W held by the holder 7 when seen from an upper side.

In the third embodiment, an inclination adjusting mechanism 48 is provided to each of the plurality of LED lamps 45. The inclination adjusting mechanism 48 can incline the LED lamps 45 to adjust an inclination thereof.

In the third embodiment, as illustrated in FIG. 9, the plurality of inclination adjusting mechanisms 48 inclines the plurality of LED lamps 45 with respect to a horizontal plane so that the center of the concentric circle is directed to the peripheral edge part of the semiconductor wafer W. That is to say, the LED lamp 45 is greatly inclined with respect to the horizontal plane as it is closer to the center of the concentric circle, and the LED lamp 45 is hardly inclined in the outer periphery of the concentric circle.

As described above, when the semiconductor wafer W is preheated by the plurality of LED lamps 45, the temperature of the peripheral edge part thereof decrease more easily than that of the center portion thereof. In the third embodiment, the inclination of each of the plurality of LED lamps 45 is individually adjusted by the inclination adjusting mechanism 48, and the plurality of LED lamps 45 are disposed to be inclined with respect to the horizontal plane so that the center of the concentric circle is directed to the peripheral edge part of the semiconductor wafer W. Accordingly, when the semiconductor wafer W is irradiated with light from the plurality of LED lamps 45, illuminance of the peripheral edge part of the semiconductor wafer W is relatively high compared with the center portion thereof, and uniformity of the in-plane temperature distribution of the semiconductor wafer W can be improved.

### Fourth Embodiment

Next, a fourth embodiment according to the present invention will be described. A whole configuration of the heat treatment apparatus 1 in the fourth embodiment is substantially the same as that of the first embodiment. A procedure of processing the semiconductor wafer W in the heat treatment apparatus 1 according to the fourth embodiment is also similar to that in the first embodiment. The fourth embodiment is different from the first embodiment in an emission intensity balance of the plurality of LED lamps 45.

The arrangement configuration of the plurality of LED lamps 45 in the fourth embodiment is the same as that in the first embodiment. That is to say, also in the fourth embodiment, the plurality of LED lamps 45 are concentrically disposed so that the central axis thereof coincides with the central axis CX of the semiconductor wafer W held by the holder 7 when seen from an upper side.

In the fourth embodiment, when the semiconductor wafer W is irradiated with light from the plurality of LED lamps 45, the power supply part 49 adjusts the emission intensity of the plurality of LED lamps 45 so that the emission intensity is higher in the outer periphery of the concentric circle. That is to say, the emission intensity of the LED lamp 45 in the outer periphery of the concentric circle is higher, and the emission intensity of the LED lamp 45 closer to the center of the concentric circle is lower.

In the fourth embodiment, the emission intensity of the plurality of LED lamps 45 is individually adjusted by the power supply part 49, and the emission intensity of the LED lamp 45 is increased as it is located closer to the outer periphery of the concentric circle. Accordingly, when the semiconductor wafer W is irradiated with light from the plurality of LED lamps 45, illuminance of the peripheral edge part of the semiconductor wafer W where decrease in temperature occurs easily is relatively high compared with the center portion thereof, and uniformity of the in-plane temperature distribution of the semiconductor wafer W can be improved.

### Fifth Embodiment

Next, a fifth embodiment according to the present invention will be described. A whole configuration of the heat treatment apparatus 1 in the fifth embodiment is substantially the same as that of the first embodiment. A procedure of processing the semiconductor wafer W in the heat treatment apparatus 1 according to the fifth embodiment is also similar to that in the first embodiment. The fifth embodiment is different from the first embodiment in an emission time balance of the plurality of LED lamps 45.

The arrangement configuration of the plurality of LED lamps 45 in the fifth embodiment is the same as that in the first embodiment. That is to say, also in the fifth embodiment, the plurality of LED lamps 45 are concentrically disposed so that the central axis thereof coincides with the central axis CX of the semiconductor wafer W held by the holder 7 when seen from an upper side.

In the fifth embodiment, when the semiconductor wafer W is irradiated with light from the plurality of LED lamps 45, the power supply part 49 adjusts the emission time of the plurality of LED lamps 45 so that the emission time is longer in the outer periphery of the concentric circle. That is to say, the emission time of the LED lamp 45 in the outer periphery of the concentric circle is longer, and the emission time of the LED lamp 45 closer to the center of the concentric circle is shorter. Specifically, the LED lamp 45 is turned on earlier in the outer periphery of the concentric circle at the time of preheating the semiconductor wafer W. The plurality of LED lamps 45 are turned off at the same time.

In the fifth embodiment, the emission time of the plurality of LED lamps 45 is individually adjusted by the power supply part 49, and the emission time of the LED lamp 45 is increased as it is located closer to the outer periphery of the concentric circle. Accordingly, when the semiconductor wafer W is irradiated with light from the plurality of LED lamps 45, the emission time to the peripheral edge part of the semiconductor wafer W where decrease in temperature occurs easily is long compared with the center portion thereof, and uniformity of the in-plane temperature distribution of the semiconductor wafer W can be improved.

### Modification Example

While the embodiments according to the present invention have been described hereinabove, various modifications of the present invention are possible in addition to those described above without departing from the scope and spirit of the present invention. For example, in each embodiment described above, the plurality of LED lamps 45 are concentrically disposed, however, the configuration is not limited thereto. For example, the plurality of LED lamps 45 may be disposed at regular intervals in a lattice form, or the plurality of LED lamps having a hexagonal prism shape may be disposed in a honeycomb form.

In the second embodiment to the fifth embodiment, various parameters of the plurality of LED lamps 45 are individually adjusted, however, the plurality of LED lamps 45 may be divided into some lamp groups to adjust a parameter for each lamp group. For example, it is also applicable that the plurality of LED lamps 45 concentrically disposed are divided into a center lamp group facing the center portion of the semiconductor wafer W, a peripheral lamp group facing the peripheral edge part of the semiconductor wafer W, and a middle lamp group between the center lamp group and the peripheral lamp group, and a parameter such as a height position may be adjusted for each lamp group. By doing so, it is sufficient to provide an adjusting mechanism such as the height position adjusting mechanism 47 for each lamp group, thus the number of necessary adjusting mechanisms can be reduced.

Two or more of the configurations of the second embodiment to the fifth embodiment may be combined. For example, it is also applicable that the plurality of LED lamps 45 are disposed so that the outer periphery of the concentric circle is closer to the semiconductor wafer W, and the emission intensity of the LED lamp 45 is increased as it is located closer to the outer periphery of the concentric circle.

In the second embodiment to the fifth embodiment, the illuminance of the peripheral edge part of the semiconductor wafer W is relatively high, however, the configuration is not limited thereto. A parameter of the plurality of LED lamps 45 may be adjusted so that the illuminance of an in-plane temperature reduction region (a so-called cold spot) of the semiconductor wafer W is relatively high. For example, when the temperature reduction region appears inside the semiconductor wafer W, the emission intensity of the LED lamp 45 facing the temperature reduction region may be increased.

Although the 30 flash lamps FL are provided in the flash heating part 5 according to the aforementioned embodiment, the present invention is not limited thereto. Any number of flash lamps FL may be provided. The flash lamps FL are not limited to the xenon flash lamps, but may be krypton flash lamps.

The substrate to be treated by the heat treatment apparatus 1 is not limited to the semiconductor wafer, but a glass substrate used for a flat panel display in a liquid crystal display device, for example, or a substrate for a solar cell are also applicable.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus heating a substrate by irradiating the substrate with light, comprising:
a chamber housing a substrate;
a holder holding the substrate in the chamber;
a plurality of LED lamps provided on one side of the chamber to irradiate the substrate held by the holder with light having a wavelength of 900 nm or less;
a flash lamp provided on another side of the chamber to irradiate the substrate held by the holder with a flash of light; and
a quartz window provided in the chamber and disposed between the holder and the plurality of LED lamps.

2. The heat treatment apparatus according to claim 1, wherein
the plurality of LED lamps are concentrically disposed so that a central axis of the LED lamps coincides with a central axis of the substrate held by the holder.

3. The heat treatment apparatus according to claim 2, wherein
the plurality of LED lamps are disposed so that an outer periphery of a concentric circle is closer to the substrate.

4. The heat treatment apparatus according to claim 2, wherein
the plurality of LED lamps are disposed so that a center of a concentric circle is inclined more with respect to a horizontal plane to be directed to a peripheral edge part of the substrate.

5. The heat treatment apparatus according to claim 2, wherein
the plurality of LED lamps have higher emission intensity at an outer periphery of a concentric circle.

6. The heat treatment apparatus according to claim 2, wherein
the plurality of LED lamps have a longer irradiation time at an outer periphery of a concentric circle.

7. The heat treatment apparatus according to claim 1, further comprising a mechanism adjusting a height position and/or an inclination angle of the plurality of LED lamps.

8. A heat treatment method of heating a substrate by irradiating the substrate with light, comprising steps of:
(a) irradiating a substrate held by a holder in a chamber with light having a wavelength of 900 nm or less from a plurality of LED lamps provided on one side of the chamber to heat the substrate; and
(b) irradiating the substrate held by the holder with a flash of light from a flash lamp provided on another side of the chamber to heat the substrate.

9. The heat treatment method according to claim 8, wherein
the plurality of LED lamps are concentrically disposed so that a central axis of the LED lamps coincides with a central axis of the substrate held by the holder.

10. The heat treatment method according to claim 9, further comprising a step of
adjusting a height position of the plurality of LED lamps so that an outer periphery of a concentric circle is closer to the substrate.

11. The heat treatment method according to claim 9, further comprising a step of
inclining the plurality of LED lamps with respect to a horizontal plane so that a center of a concentric circle is directed more to a peripheral edge part of the substrate.

12. The heat treatment method according to claim 9, further comprising a step of
adjusting emission intensity of the plurality of LED lamps so that emission intensity is higher at an outer periphery of a concentric circle.

13. The heat treatment method according to claim 9, further comprising a step of
adjusting an irradiation time of the plurality of LED lamps so that an irradiation time is longer at an outer periphery of a concentric circle.
